(19) United States
(12) Patent Application Publication
(10) Pub. No.: US 2025/0183879 A1
(43) Pub. Date: Jun. 5, 2025

(54) PHASE ADJUSTMENT CIRCUIT

(71) Applicant: Nippon Telegraph and Telephone Corporation, Tokyo (JP)

(72) Inventors: Tsutomu Takeya, Tokyo (JP); Munehiko Nagatani, Tokyo (JP); Teruo Jo, Tokyo (JP); Hitoshi Wakita, Tokyo (JP); Hiroyuki Takahashi, Tokyo (JP)

(21) Appl. No.: 18/718,692

(22) PCT Filed: Dec. 16, 2021
(86) PCT No.: PCT/JP2021/046504

§ 371 Date: Dec. 11, 2024

(51) Int. Cl. H03K 5/01; H03K 5/00; H03K 17/60

(52) U.S. Cl. CPC H03K 5/01; H03K 17/60; H03K 2005/00019; H03K 2005/00286

(57) ABSTRACT

In some implementations, the device may include a clock generator configured to generate a sinusoidal clock signal. The device may include a delay circuit configured to delay a signal output from the clock generator. The device may also include a first multiplier configured to output a signal obtained by multiplying an amplitude of the signal output from the clock generator by a first constant. Additionally, the device may include a second multiplier configured to output a signal obtained by multiplying an amplitude of the signal output from the delay circuit by a second constant. Also, the device may include an adder configured to add the signal output from the first multiplier and the signal output from the second multiplier.

### CROSS-REFERENCE TO RELATED APPLICATIONS

This application is a national phase entry of PCT Application No. PCT/JP2021/046504, filed on Dec. 16, 2021, which application is hereby incorporated herein by reference.

### TECHNICAL FIELD

The present invention relates to a phase adjustment circuit of a sine wave.

### BACKGROUND

At present, the sine wave plays an important role. In communication, the sine wave may be used for generating a carrier wave, or the sine wave may be used as a clock. In the communication, the clock is used not only as the carrier wave, but also as a timing reference for determining data.

When the clock is used as the timing reference for such data determination, it is necessary to adjust the phase of the clock and perform data determination at an appropriate timing. As a method for performing the data determination at an appropriate timing, there is clock data recovery. As means for realizing clock data recovery, a configuration using a phase comparator and a phase adjustment circuit is known. In this configuration, phases are compared by some means, and a desired phase is generated on the basis of the comparison result.

In the related art, as the phase adjustment circuit, a configuration disclosed in NPL 1 is known. A configuration of the phase adjustment circuit of the related art is shown in FIG. 8. In the configuration shown in FIG. 8, by adding a sine wave sin ωt as a reference and a sine wave cos ωt having a fixed phase difference of π/2 with respect to the sine wave sin ωt by an adder 103, an arbitrary intermediate phase waveform is generated. The sine waves sin ωt and cos ωt are multiplied by constants A and B by multipliers 101 and 102, respectively. The following Equation is established from equation of trigonometric function synthesis.

$$\begin{matrix}[ Math . 1 ] & \\ A sin ω t + B cos ω t = \sqrt{{A}^{2} + {B}^{2}} sin ( ω t + α ) & ( 1 )\end{matrix}$$

α in Equation (1) is as follows:

$$\begin{matrix}[ Math . 2 ] & \\ cos α = \frac{A}{\sqrt{{A}^{2} + {B}^{2}}} , sin α = \frac{B}{\sqrt{{A}^{2} + {B}^{2}}} & ( 2 )\end{matrix}$$

In the configuration of FIG. 8, sine waves sin ωt and cos ωt are generated, using a Quadrature-VCO (Voltage Controlled Oscillator) 100. However, since the Quadrature-VCO 100 has a lower oscillation frequency in terms of structure, there is a problem that it is difficult to use in a limit region of a device. In addition, although a method of using a 90 degree hybrid is known as a method of producing a sine wave having a fixed phase difference of π/2 from the sine wave, there is a problem that it operates only at a specific frequency when using the 90 degree hybrid.

### CITATION LIST

### Non Patent Literature

[NPL 1] Arun Goyal, et al., “A High-Resolution Digital Phase Interpolator Based CDR with a Half-Rate Hybrid Phase Detector”, 2019 IEEE International Symposium on Circuits and Systems (ISCAS), May 2019

### SUMMARY

### Technical Problem

The present invention is made to solve above problem, and an object thereof is to provide a phase adjustment circuit that can be used in a wide range of frequencies.

### Solution to Problem

A phase adjustment circuit of embodiments of the present invention includes: a clock generation unit configured to generate a sinusoidal clock signal; a delay unit configured to delay a signal output from the clock generation unit; a first multiplying unit configured to output a signal obtained by multiplying an amplitude of the signal output from the clock generation unit by a first constant; a second multiplying unit configured to output a signal obtained by multiplying the amplitude of the signal output from the delay unit by a second constant; and an adding unit configured to add the signal output from the first multiplying unit and the signal output from the second multiplying unit.

I In one configuration example of the phase adjustment circuit of the present invention, the first multiplying unit includes a first transistor in which a first control signal or a signal of a negative phase side of the clock signal of a differential type is input to a base or a gate, and a signal of a positive phase side is output from a collector or a drain; a second transistor in which a second control signal or a signal of a positive phase side of the clock signal of a differential type is input to a base or a gate, and a signal of a negative phase side is output from a collector or a drain; a third transistor in which the first control signal or the signal of the negative phase side of the clock signal of the differential type is input to a base or a gate, and the signal of the negative phase side is output from a collector or a drain; a fourth transistor in which the second control signal or the signal of the positive phase side of the clock signal of the differential type is input to a base or a gate, and the signal of the positive phase side is output from a collector or a drain; a fifth transistor in which the signal of the positive phase side of the clock signal of the differential type or the second control signal is input to a base or a gate, and a collector or a drain is connected to an emitter or a source of the first and second transistor; a sixth transistor in which the signal of the negative phase side of the clock signal of the differential type or the first control signal is input to a base or a gate, and a collector or a drain is connected to emitters or sources of the third and fourth transistors; a seventh transistor in which a bias voltage is applied to a base or a gate; a first resistor which has one end connected to a power supply voltage, and the other end connected to the collector or the drain of the first and fourth transistors; a second resistor which has one end connected to the power supply voltage, and the other end connected to the collector or the drain of the second and third transistors; a third resistor which has one end connected to an emitter or a source of the fifth transistor, and the other end connected to a collector or a drain of the seventh transistor; a fourth resistor which has one end connected to an emitter or a source of the sixth transistor, and the other end connected to the collector or the drain of the seventh transistor; and a fifth resistor which has one end connected to an emitter or a source of the seventh transistor, and the other end connected to ground. The second multiplying unit includes an eighth transistor in which a third control signal or a signal of a negative phase side signal of the differential signal output from the delay unit is input to a base or a gate, and a signal of a positive phase is output from a collector or a drain; a ninth transistor in which a fourth control signal or a signal of a positive phase signal of the differential signal output from the delay unit is input to a base or a gate, and a signal of a negative phase is output from a collector or a drain; a tenth transistor in which the third control signal or the signal of the negative phase side signal of the differential signal output from the delay unit is input to a base or a gate, and the signal of the negative phase side is output from a collector or a drain; an eleventh transistor in which the fourth control signal or the signal of the positive phase signal of the differential signal output from the delay unit is input to a base or a gate, and the signal of the positive phase is output from a collector or a drain; a twelfth transistor in which the signal of the positive phase side of the differential signal output from the delay unit or the fourth control signal is input to a base or a gate, and a collector or a drain is connected to an emitter or a source of the eighth and ninth transistors; a thirteenth transistor in which the signal of the negative phase side of the differential signal output from the delay unit or the third control signal is input to a base or a gate, and a collector or a drain is connected to an emitter or a source of the tenth and eleventh transistors; a fourteenth transistor in which a bias voltage is applied to a base or a gate; a sixth resistor which has one end connected to the power supply voltage, and the other end connected to a collector or a drain of the eighth and eleventh transistors; a seventh resistor which has one end connected to the power supply voltage, and the other end connected to the collector or the drain of the ninth and tenth transistors; an eighth resistor which has one end connected to an emitter or a source of the twelfth transistor, and the other end connected to a collector or a drain of the fourteenth transistor; a ninth resistor which has one end connected to an emitter or a source of the thirteenth transistor, and the other end connected to the collector or the drain of the fourteenth transistor; and a tenth resistor which has one end connected to an emitter or a source of the fourteenth transistor, and the other end connected to ground.

Further, in one configuration example of the phase adjustment circuit of the present invention, the adding unit includes a fifteenth transistor in which the signal of the negative phase side of the differential signal output from the first multiplying unit is input to a base or a gate, and the signal of the positive phase side is output from a collector or a drain; a sixteenth transistor in which the signal of the positive phase side of the differential signal output from the first multiplying unit is input to a base or a gate, and the signal of the positive phase side is output from a collector or a drain; a seventeenth transistor in which the signal of the positive phase side of the differential signal output from the second multiplying unit is input to a base or a gate, and the signal of the negative phase side is output from a collector or a drain; an eighteenth transistor in which the signal of the negative phase side of the differential signal output from the second multiplying unit is input to a base or a gate, and the signal of the positive phase side is output from a collector or a drain; nineteenth and twentieth transistors in which a bias voltage is applied to a base or a gate; an eleventh resistor which has one end connected to the power supply voltage, and the other end connected to a collector or a drain of the fifteenth and eighteenth transistors; a twelfth resistor which has one end connected to the power supply voltage, and the other end connected to a collector or a drain of the sixteenth and seventeenth transistors; a thirteenth resistor which has one end connected to an emitter or a source of the fifteenth transistor, and the other end connected to a collector or a drain of the nineteenth transistor; a fourteenth resistor which has one end connected to an emitter or a source of the sixteenth transistor, and the other end connected to the collector or the drain of the nineteenth transistor; a fifteenth resistor which has one end connected to an emitter or a source of the seventeenth transistor, and the other end connected to a collector or a drain of the twentieth transistor; a sixteenth resistor which has one end connected to an emitter or a source of the eighteenth transistor, and the other end connected to the collector or the drain of the twentieth transistor; a seventeenth resistor which has one end connected to an emitter or a source of the nineteenth transistor, and the other end connected to ground; and an eighteenth resistor which has one end connected to an emitter or a source of the twentieth transistor, and the other end connected to ground.

Further, in one configuration example of the phase adjustment circuit of the present invention, the first and second multiplying units and the adding unit are configured to include a first transistor in which the first control signal or the signal of the negative phase side of the clock signal of the differential type is input to a base or a gate, and the signal of the positive phase side is output from a collector or a drain; a second transistor in which the second control signal or the signal of the positive phase side of the clock signal of the differential type is input to a base or a gate, and the signal of the negative phase side is output from a collector or a drain; a third transistor in which the first control signal or the signal of the negative phase side of the clock signal of the differential type is input to a base or a gate, and the signal of the negative phase side is output from a collector or a drain; a fourth transistor in which the second control signal or the signal of the positive phase side of the clock signal of the differential type is input to a base or a gate, and the signal of the positive phase side is output from a collector or a drain; a fifth transistor in which the signal of the positive phase side of the clock signal of the differential type or the second control signal is input to a base or a gate, and a collector or a drain is connected to emitters or sources of the first and second transistors; a sixth transistor in which the signal of the negative phase side of the clock signal of the differential type or the first control signal is input to a base or a gate, and a collector or a drain is connected to emitters or sources of the third and fourth transistors; a seventh transistor in which a bias voltage is applied to a base or a gate; an eighth transistor in which a third control signal or the signal of the negative phase side of the differential signal output from the delay unit is input to a base or a gate, and the signal of the positive phase side is output from a collector or a drain; a ninth transistor in which a fourth control signal or the signal of the positive phase side of the differential signal output from the delay unit is input to a base or a gate, and the signal of the negative phase side is output from a collector or a drain; a tenth transistor in which the third control signal or the signal of the negative phase side of the differential signal output from the delay unit is input to a base or a gate, and the signal of the negative phase side is output from a collector or a drain; an eleventh transistor in which the fourth control signal or the signal of the positive phase side of the differential signal output from the delay unit is input to a base or a gate, and the signal of the positive phase side is output from a collector or a drain; a twelfth transistor in which the signal of the positive phase side of the differential signal output from the delay unit or the fourth control signal is input to a base or a gate, and a collector or a drain is connected to the emitters or sources of the eighth and ninth transistors; a thirteenth transistor in which the signal of the negative phase side of the differential signal output from the delay unit or the third control signal is input to a base or a gate, and a collector or a drain is connected to the emitters or sources of the tenth and eleventh transistors; a fourteenth transistor in which a bias voltage is applied to a base or a gate; a first resistor which has one end connected to the power supply voltage, and the other end connected to the collectors or drains of the first, fourth, eighth and eleventh transistors; a second resistor which has one end connected to the power supply voltage, and the other end connected to the collectors or drains of the second, third, ninth and tenth transistors; a third resistor which has one end connected to an emitter or a source of the fifth transistor, and the other end connected to a collector or a drain of the seventh transistor; a fourth resistor which has one end connected to an emitter or a source of the sixth transistor, and the other end connected to the collector or the drain of the seventh transistor; a fifth resistor which has one end connected to an emitter or a source of the seventh transistor, and the other end connected to ground; a sixth resistor which has one end connected to an emitter or a source of the twelfth transistor, and the other end connected to a collector or a drain of the fourteenth transistor; a seventh resistor which has one end connected to an emitter or a source of the thirteenth transistor, and the other end connected to the collector or the drain of the fourteenth transistor; and an eighth resistor which has one end connected to an emitter or a source of the fourteenth transistor, and the other end connected to ground.

One configuration example of the phase adjustment circuit of the present invention includes a plurality of delay units having different delay amounts, and further includes a switch which is inserted between the plurality of delay units and the second multiplying unit and configured to select any one output of the plurality of delay units.

One example of the configuration of the phase adjustment circuit of the present invention further includes a level adjusting unit configured to perform an amplitude adjustment of the signal output from the adding unit.

### Advantageous Effects of Invention

According to embodiments of the present invention, by providing a clock generation unit, a delay unit, first and second multiplying units and an adding unit, it is not necessary to use a conventional Quadrature-VCO as a clock generation unit, and an LC-VCO made up of a general LC oscillator can be used as the clock generation unit. In addition, the present invention can be used in a wide range of frequencies, unlike a configuration in which a 90-degree hybrid is used as the clock generation unit.

### BRIEF DESCRIPTION OF THE DRAWINGS

FIG. 1 is a block diagram showing a configuration of a phase adjustment circuit according to a first example of the present invention.

FIG. 2 is a diagram showing simulation results of the phase adjustment circuit according to the first example of the present invention.

FIG. 3 is a block diagram showing another configuration of the phase adjustment circuit according to the first example of the present invention.

FIG. 4 is a circuit diagram showing the configuration of a multiplying unit according to the first example of the present invention.

FIG. 5 is a circuit diagram showing a configuration of an adding unit according to the first example of the present invention.

FIG. 6 is a circuit diagram showing configurations of the multiplying unit and the adding unit according to the first example of the present invention.

FIG. 7 is a block diagram showing the configuration of a phase adjustment circuit according to a second example of the present invention.

FIG. 8 is a block diagram showing a configuration of a phase adjustment circuit of the related art.

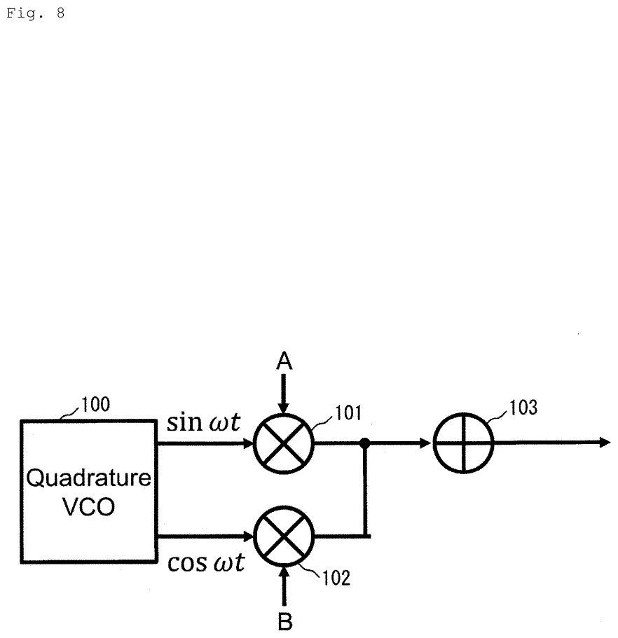

### DETAILED DESCRIPTION OF ILLUSTRATIVE EMBODIMENTS

### First Example

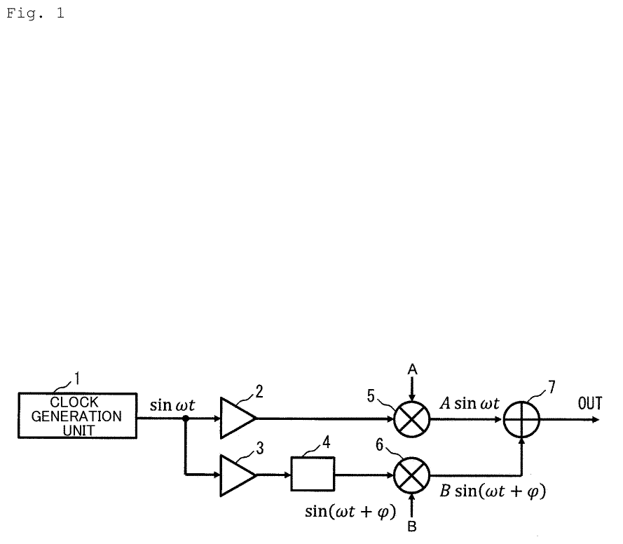

Referring to the drawings, a description will be given of examples of the present invention. FIG. 1 is a block diagram showing a configuration of a phase adjustment circuit according to a first example of the present invention. The phase adjustment circuit includes a clock generation unit 1 which generates a sinusoidal clock signal, buffer units 2 and 3 which receive a signal output from the clock generation unit 1 as an input, a delay unit 4 which delays the signal output from the buffer unit 3, a multiplying unit 5 which outputs a signal obtained by multiplying an amplitude of the signal output from the buffer unit 2 by A (first constant), a multiplying unit 6 which outputs a signal obtained by multiplying an amplitude of the signal output from the delay unit 4 by B (second constant), and an adding unit 7 which adds the signal output from the multiplying unit 5 and the signal output from the multiplying unit 6.

In this example, by adding a sine wave sin ωt serving as a reference and a sine wave sin (ωt+φ) having a phase different by φ at an arbitrary magnification, an arbitrary waveform can be generated. That is, an output signal OUT of the adding unit 7 is expressed by the following Equation.

$$[ Math . 3 ]$$

$$OUT = A sin ω t + B sin ( ω t + φ ) = Im [ {Ae}^{j ω t} + {Be}^{j ( ω t + φ )} ] = Im [ ( A + {Be}^{j φ} ) {e}^{j ω t} ] = Im [ {re}^{j ρ} {e}^{j ω t} ] \qquad ( 3 )$$

In Equation (3), ejωt represents a reference sin wave. It can be seen from Equation (3) that the sin wave having the reference frequency and the sin wave having the phase different by ρ from the reference phase can be generated, by adding the sin wave having the reference frequency and the sin wave having arbitrary phase different by φ.

A detailed description will be given below. Since the amount of change in the output phase may be calculated by calculating re^{jρ}, when rearranging Equation (3), the following Equation is obtained.

$$[ Math . 4 ]$$

$${re}^{j ρ} = A + {Be}^{j φ} = A + B cos ( φ ) + jB sin ( φ ) = B [ \frac{A}{B} + cos ( φ ) + j sin ( φ ) ] = B [ x + cos ( φ ) + j sin ( φ ) ] \qquad ( 4 )$$

From Equation (4), the phase angle ρ is given by Equation (5).

$$[ Math . 5 ]$$

$$ρ = arg ( B [ x + cos ( φ ) + j sin ( φ ) ] ) = arg ( x + cos ( φ ) + j sin ( φ ) ) \qquad ( 5 )$$

A value range when the phase angle ρ is controlled by the amplitudes A and B is considered. Although the range of the output amplitudes A and B on the circuit is finite with o as the center, since A and B are independent, x=A/BE [−∞,+∞], and an arbitrary real number can be selected as the amplitudes A and B. The sign of x can be determined by the combination of the signs of the amplitudes A and B, and the denominator B can be reduced as much as possible to increase the value of x.

Further, when y=x+cos (φ), y=(A/B)+cos (φ)∈[−∞,+∞] is clearly expressed. Therefore, ρ=arg (x+cos (φ)+j sin (φ))=arg (y+j sin (φ)) can take a value of 0 to π [rad] under conditions of sin (φ)≠0. It is also clear that ρ=arg (x+cos (φ)+j sin (φ))=arg (y+j sin (φ)) can take −π to 0 [rad], assuming that the polarity of B is reversed. That is, according to this example, a signal in which an input sine wave is adjusted to an arbitrary phase can be output.

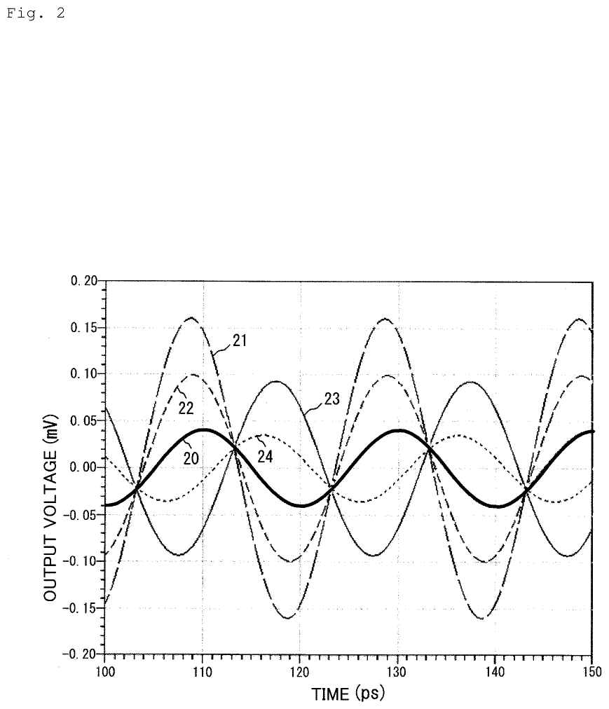

FIG. 2 shows a result of confirmation by circuit simulation that the phase of the sine wave changes by the phase adjustment circuit of this example. Here, sine waves 21 to 24 are shown in which the values of amplitudes A and B in Equations (3) to (5) are changed and the phase is changed, by setting the frequency of the sine wave 20 input from the clock generation unit 1 to 50 GHz (period 20 ps), and changing the control voltages of the multiplying units 5 and 6. In the example of FIG. 2, adjustment for equalizing the amplitudes of the sine waves 20 to 24 is not performed to make the phase change easy to understand.

Although there are many methods for realizing the delay unit 4, the delay unit 4 may be realized by, for example, propagation delay of wiring. In particular, a transmission line may be used as a wiring for realizing the delay unit 4 to cope with a high frequency. The type and structure of the transmission line are not limited. A coplanar line or a microstrip line may be used as the transmission line.

Further, as the delay unit 4, an arbitrary number of amplifiers may be cascade-connected. Further, the delay unit 4 may be realized by a lumped constant element. For example, the delay unit 4 can be realized by an LCR resonance circuit. Further, the delay unit 4 may be realized by combining the wiring, the amplifier, and the lumped constant element.

Although a sine wave sin (ωt+φ) having a phase different from that of the sine wave sin ωt by φ can be generated by the delay amount of the delay unit 4, in the case of φ=πn (n is an arbitrary integer), a phase adjustment cannot be realized because no phase difference occurs between sin ωt and sin (ωt+φ). That is, at the time of φ=π, the sign of B is only changed without the phase difference only by −sin.

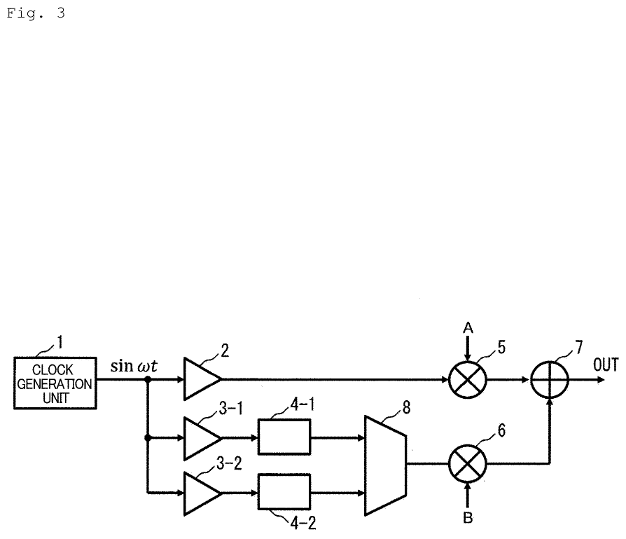

Therefore, as shown in FIG. 3, a plurality of delay units 4-1 and 4-2 having different delay amounts are provided, and a plurality of input buffer units 3-1 and 3-2 are provided to correspond to each of the delay units 4-1 and 4-2, and a switch 8 may be inserted between the delay units 4-1 and 4-2 and the multiplying unit 6. The delay amount can be switched by selecting any one output of the plurality of delay units 4-1 and 4-2 having different delay amounts by the switch 8.

The plurality of delay units 4-1 and 4-2 having different delay amounts may be realized by changing the length of a transmission line or by changing the number of stages of amplifiers cascade-connected.

Although the number of delay units 4-1 and 4-2 is two in the example of FIG. 3, it is needless to say that three or more delay units may be switched.

In the range of 0<|φ|<π, it is apparent that a phase difference occurs between sin ωt and sin (ωt+Q). Therefore, by designing the delay unit 4 to satisfy 0<|φ|<π at the assumed maximum frequency of the sine wave to be a target of the phase adjustment in the phase adjustment circuit of this example, an arbitrary phase difference can be realized without switching the delay amount. When 0<|φ|<π is satisfied, since the delay amount of the delay unit 4 can be minimized, the circuit area, cost and power consumption can be reduced.

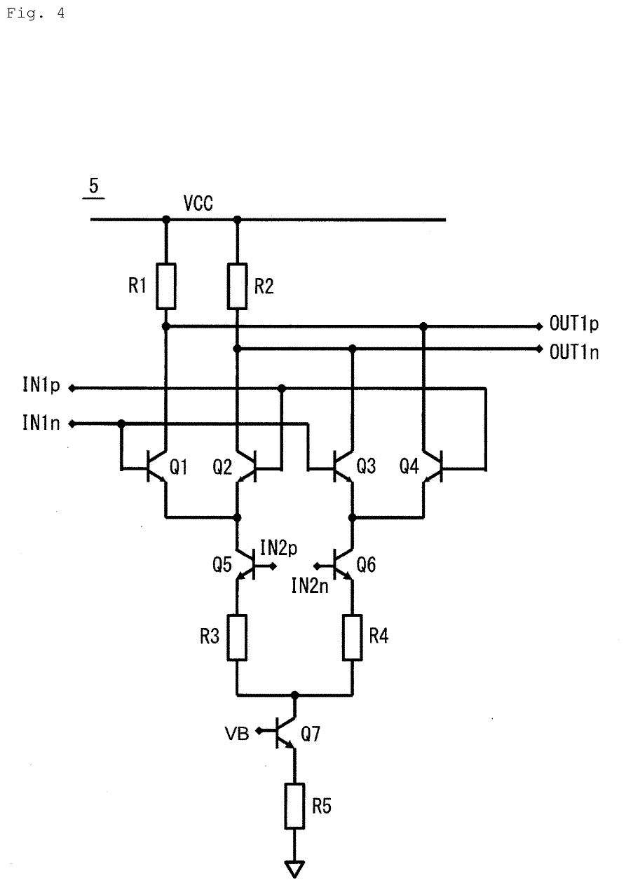

Gilbert cells can be used as the multiplying units 5 and 6. As shown in FIG. 4, the multiplying unit 5 includes an NPN bipolar transistor Q1 in which a control signal IN1n (first control signal or third control signal) is input to a base and an output signal OUT1p on a positive phase side is output from a collector; an NPN bipolar transistor Q2 which a control signal IN1p (second control signal or fourth control signal) is input to a base and an output signal OUT1n of a negative phase side is output from a collector; an NPN bipolar transistor Q3 in which a control signal IN1n is input to a base and an output signal OUT1n of the negative phase side is output from a collector; an NPN bipolar transistor Q4 in which a control signal IN1p is input to a base and an output signal OUT1p of the positive phase side is output from a collector; an NPN bipolar transistor Q5 in which a signal IN2p of the positive phase side of the differential signal output from the buffer unit 2 is input to a base and a collector is connected to emitters of the transistors Q1 and Q2; an NPN bipolar transistor Q6 in which a signal IN2n of the negative phase side of the differential signal output from the buffer unit 2 and a collector is connected to emitters of the transistors Q3 and Q4; an NPN bipolar transistor Q7 in which a bias voltage VB is applied to a base, a resistor R1 which has one end connected to a power supply voltage VCC and the other end connected to the collectors of the transistors Q1 and Q4; a resistor R2 which has one end connected to the power supply voltage VCC and the other end connected to the collectors of the transistors Q2 and Q3; a resistor R3 which has one end connected to the emitter of the transistor Q5 and the other end connected to the collector of the transistor Q7; a resistor R4 which has one end connected to the emitter of the transistor Q6 and the other end connected to the collector of the transistor Q7; and a resistor R5 which has one end connected to the emitter of the transistor Q7 and the other end connected to the ground.

An amplification factor (the amplitude A) of the multiplying unit 5 can be controlled by a voltage difference between the control signals IN1p and IN1n.

The configuration of the multiplying unit 6 is the same as that of the multiplying unit 5. In the case of the multiplying unit 6, differential signals IN2p and IN2n output from the delay unit 4 or the switch 8 are input to transistors Q5 and Q6. The amplification factor (the amplitude B) of the multiplying unit 6 can be controlled by the voltage difference between the control signals IN1p and IN1n.

In the Gilbert cell, (IN1p−In1n)×(IN2p−In2n) obtained by multiplying (IN1p−In1n) and (IN2p−In2n) becomes an output (OUT1p−OUT1n) in terms of the structure. Therefore, the differential signals output from the buffer unit 2, the delay unit 4 and the switch 8 are allocated to IN1p and IN1n, IN2p and IN2n may be used as control signals.

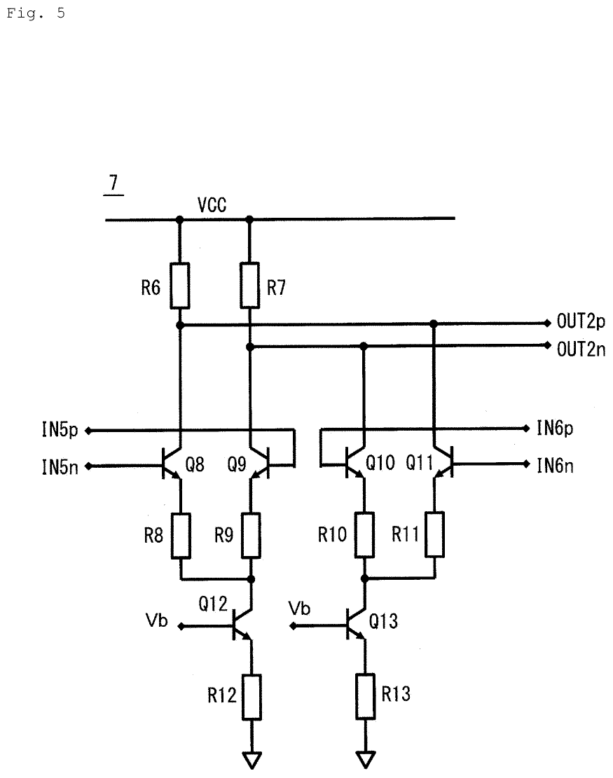

As the adding unit 7, a current mode logic (CML) block of a current addition base can be used. As shown in FIG. 5, the adding unit 7 includes an NPN bipolar transistor Q8 in which a signal IN5n on the negative phase side of the differential signal output from the multiplying unit 5 is input to a base and an output signal OUT2p of the positive phase side is output from a collector; an NPN bipolar transistor Q9 in which a signal IN5p of the positive phase side of the differential signal output from the multiplying unit 5 is input to a base and an output signal OUT2n of the negative phase side is output from a collector; an NPN bipolar transistor Q10 in which a signal IN6p of the positive phase side of the differential signal output from the multiplying unit 6 is input to a base and an output signal OUT2n of the negative phase side is output from a collector; an NPN bipolar transistor Q11 in which a signal IN6n of the negative phase side of the differential signal output from the multiplying unit 6 is input to a base, and an output signal OUT2p of the positive phase side is output from a collector; an NPN bipolar transistors Q12 and Q13 in which a bias voltage Vb is applied to a base; a resistor R6 which has one end connected to the power supply voltage VCC and the other end connected to the collectors of the transistors Q8 and Q11; a resistor Ry which has one end connected to the power supply voltage VCC and the other end connected to the collectors of the transistors Q9 and Q10; a resistor R8 which has one end connected to the emitter of the transistor Q8 and the other end connected to the collector of the transistor Q12; a resistor R9 which has one end connected to the emitter of the transistor Q9 and the other end connected to the collector of the transistor Q12; a resistor R10 which has one end connected to the emitter of the transistor Q10 and the other end connected to the collector of the transistor Q13; a resistor R11 which has one end connected to the emitter of the transistor Q11 and the other end connected to the collector of the transistor Q13; a resistor R12 which has one end connected to the emitter of the transistor Q12 and the other end connected to the ground; and a resistor R13 which has one end connected to the emitter of the transistor Q13 and the other end connected to the ground.

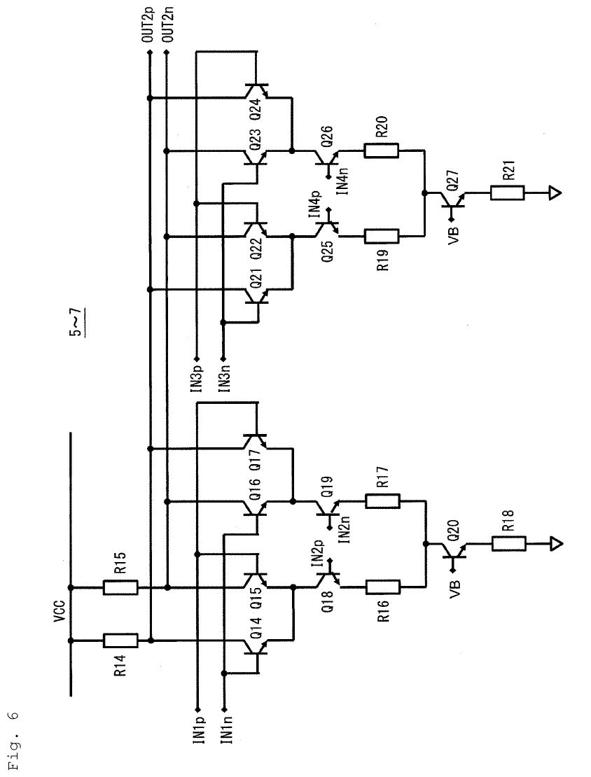

Further, by combining the Gilbert cell and the CML, a configuration in which the multiplying units 5 and 6 and the adding unit 7 are integrated may be realized. This configuration includes, as shown in FIG. 6, an NPN bipolar transistor Q14 in which a control signal IN1n (first control signal) is input to a base, and an output signal OUT2p of a positive phase side is output from a collector; an NPN bipolar transistor Q15 in which a control signal IN1p (second control signal) is input to a base, and an output signal OUT2n of the negative phase side is output from a collector; an NPN bipolar transistor Q16 in which the control signal IN1n is input to a base and the output signal OUT2n of the negative phase side is output from a collector; an NPN bipolar transistor Q17 in which a control signal IN1p is input to a base and an output signal OUT2p of the positive phase side is output from a collector; an NPN bipolar transistor Q18 in which a signal IN2p of the positive phase side of the differential signal output from the buffer unit 2 is input to a base, and a collector is connected to the emitters of the transistors Q14 and Q15; an NPN bipolar transistor Q19 in which a signal IN2n of the negative phase side of the differential signal output from the buffer unit 2 is input to a base, and a collector is connected to the emitters of the transistors Q16 and Q17; an NPN bipolar transistor Q20 in which a bias voltage VB is applied to a base; an NPN bipolar transistor Q21 in which a control signal IN3n (third control signal) is input to a base and the output signal OUT2p of the positive phase side is output from a collector; an NPN bipolar transistor Q22 in which a control signal IN3p (fourth control signal) is input to a base, and an output signal OUT2n of the negative phase side is output from a collector; an NPN bipolar transistor Q23 in which a control signal IN3n is input to a base and an output signal OUT2n of the negative phase side is output from a collector; an NPN bipolar transistor Q24 in which a control signal IN3p is input to a base, and the output signal OUT2p of the positive phase side is output from a collector; an NPN bipolar transistor Q25 in which a signal IN4p of the positive phase side of the differential signal output from the delay unit 4 or the switch 8 is input to a base, and a collector is connected to the emitters of the transistors Q21 and Q22; an NPN bipolar transistor Q26 in which a signal IN4n of the negative phase side of the differential signal output from the delay unit 4 or the switch 8 is input to a base, and a collector is connected to the emitters of the transistors Q23 and Q24; an NPN bipolar transistor Q27 in which a bias voltage VB is applied to a base; a resistor R14 which has one end connected to a power supply voltage VCC, and the other end connected to the collectors of the transistors Q14, Q17, Q21 and Q24; a resistor R15 which has one end connected to the power supply voltage VCC and the other end connected to the collectors of the transistors Q15, Q16, Q22 and Q23; a resistor R16 which has one end connected to the emitter of the transistor Q18 and the other end connected to the collector of the transistor Q20; a resistor R17 which has one end connected to the emitter of the transistor Q19, and the other end connected to the collector of the transistor Q20; a resistor R18 which has one end connected to the emitter of the transistor Q20, and the other end connected to the ground; a resistor R19 which has one end connected to the emitter of the transistor Q25, and the other end connected to the collector of the transistor Q27; a resistor R20 which has one end connected to the emitter of the transistor Q26, and the other end connected to the collector of the transistor Q27; and a resistor R21 which has one end connected to the emitter of the transistor Q27, and the other end connected to the ground.

The amplification factor (the amplitude A) of the multiplying unit 5 can be controlled by the voltage difference between the control signals IN1p and IN1n, and the amplification factor (the amplitude B) of the multiplying unit 6 can be controlled by the voltage difference between the control signals IN3p and IN3n. Further, as described in FIG. 4, the differential signals output from the buffer unit 2 are allocated to IN1p and IN1n, the differential signals output from the delay unit 4 or the switch 8 are allocated to IN3p and IN3, and IN2p, IN2n, IN4p and IN4n may be used as control signals.

With the configuration shown in FIG. 6, an output {(IN1p−IN1n)×(IN2p−IN2n)}+{(IN3p−IN3n)×(IN4p−IN4n)} obtained by adding the result of multiplying (IN1p−IN1n) and (IN2p−IN2n) and the result of multiplying (IN3p−IN3n) and (IN4p−IN4n) becomes (OUT2p−OUT2n).

In the configurations of FIGS. 4 to 6, the multiplying units 5 and 6 and the adding unit 7 become configurations of the differential input and the differential output. In order to correspond to the configurations of FIGS. 4 to 6, the buffer units 2, 3, 3-1, and 3-2 may be a differential output type buffer unit. Further, the delay units 4, 4-1, and 4-2 may be a differential transmission line including two transmission lines, or a configuration in which differential input and differential output type amplifiers are cascade-connected. When the switch 8 is used as in the example shown in FIG. 3, a differential input and differential output type switch may be used.

Although an example in which a bipolar transistor is used as the transistors Q1 to Q27 is shown in FIGS. 4 to 6, a MOS transistor may be used. When the MOS transistor is used, in the above description, the base may be replaced with the gate, the collector may be replaced with the drain, and the emitter may be replaced with the source.

Further, a resistor or a capacitor for gain adjustment and frequency response adjustment may be inserted into the emitter or the source of the transistor, or both of the resistor and the capacitor may be inserted into the emitter or the source of the transistor. In addition, an arbitrary amplification circuit such as an emitter follower may be provided as necessary for level adjustment or the like.

### Second Example

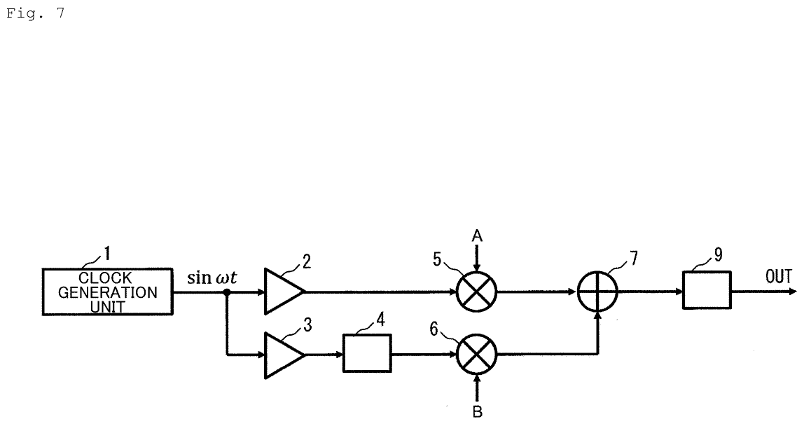

Next, a description will be given of a second example of the present invention. FIG. 7 is a diagram showing a configuration of a phase adjustment circuit according to a second example of the present invention. The phase adjustment circuit of this example is obtained by adding a level adjusting unit 9 to the output terminal of the phase adjustment circuit of the first example.

The output amplitude of the phase adjustment circuit according to the present invention changes in principle in accordance with the adjusted phase. For this reason, the level adjusting unit 9 may be provided to correspond to the varying output amplitude. As the level adjusting unit 9, there is a variable gain amplifier (VGA) capable of adjusting the output amplitude or an automatic gain control (AGC) circuit for automatically adjusting the output amplitude. The configuration of the VGA and the AGC circuit is not limited. When the AGC circuit is used, a peak detector or a power detector is connected to the output terminal (the output terminal of the adding unit 7) of the phase adjustment circuit, and the detection result is fed back to the amplifier to adjust the gain.

### INDUSTRIAL APPLICABILITY

The present invention can be applied to the technique of adjusting the phase of a sine wave.

### REFERENCE SIGNS LIST

1 Clock generation unit
2, 3, 3-1, 3-2 Buffer unit
4, 4-1, 4-2 Delay unit
5,6 Multiplying unit
7 Adding unit
8 Switch
9 Level adjusting unit
Q1 to Q27 Transistor
R1 to R21 Resistor

1-6. (canceled)

7. A phase adjustment circuit comprising:
a clock generator configured to generate a sinusoidal clock signal;
a delay circuit configured to delay a signal output from the clock generator;
a first multiplier configured to output a signal obtained by multiplying an amplitude of the signal output from the clock generator by a first constant;
a second multiplier configured to output a signal obtained by multiplying an amplitude of the signal output from the delay circuit by a second constant; and
an adder configured to add the signal output from the first multiplier and the signal output from the second multiplier.

8. The phase adjustment circuit according to claim 7, wherein the first multiplier includes:
a first transistor including a base or a gate to which a first control signal or a signal of a negative phase side of the clock signal of a differential type is input, and a collector or a drain from which a signal of a positive phase side is output;
a second transistor including a base or a gate to which a second control signal or a signal of a positive phase side of the clock signal of the differential type is input, and a collector or a drain from which a signal of a negative phase side is output;
a third transistor including a base or a gate to which the first control signal or the signal of the negative phase side of the clock signal of the differential type is input, and a collector or a drain from which the signal of the negative phase side is output;
a fourth transistor including a base or a gate to which the second control signal or the signal of the positive phase side of the clock signal of the differential type is input, and a collector or a drain from which the signal of the positive phase side is output;
a fifth transistor including a base or a gate to which the signal of the positive phase side of the clock signal of the differential type or the second control signal is input, and a collector or a drain connected to an emitter or a source of the first transistor and an emitter or a source of the second transistor;
a sixth transistor including a base or a gate to which one of the signal of the negative phase side of the clock signal of the differential type and the first control signal is input, and a collector or a drain connected to an emitter or a source of the third transistor and an emitter or a source of the fourth transistor;
a seventh transistor including a base or a gate to which a bias voltage is applied;
a first resistor including one end connected to a power supply voltage, and another end connected to a collector or a drain of the first transistor and a collector or a drain of the fourth transistor;
a second resistor including one end connected to the power supply voltage, and another end connected to a collector or a drain of the second transistor and a collector or a drain of the third transistor;
a third resistor including one end connected to an emitter or a source of the fifth transistor, and another end connected to a collector or a drain of the seventh transistor;
a fourth resistor including one end connected to an emitter or a source of the sixth transistor, and another end connected to the collector or the drain of the seventh transistor; and
a fifth resistor including one end connected to an emitter or a source of the seventh transistor, and another end connected to ground; and
wherein the second multiplier includes:
an eighth transistor including a base or a gate to which one of a third control signal and a signal of a negative phase side of a differential signal output from the delay circuit is input, and a collector or a drain from which a signal of a positive phase is output;
a ninth transistor including a base or a gate to which one of a fourth control signal and a signal of a positive phase side of the differential signal output from the delay circuit is input, and a collector or a drain from which a signal of a negative phase is output;
a tenth transistor including a base or a gate to which one of the third control signal and the signal of the negative phase side of the differential signal output from the delay circuit is input, and a collector or a drain from which the signal of the negative phase side is output;
an eleventh transistor including a base or a gate to which one of the fourth control signal and the signal of the positive phase side of the differential signal output from the delay circuit is input, and a collector or a drain from which the signal of the positive phase is output;
a twelfth transistor including a base or a gate to which one of the signal of the positive phase side of the differential signal output from the delay circuit and the fourth control signal is input, and a collector or a drain connected to an emitter or a source of the eighth transistor and an emitter or a source of the ninth transistor;
a thirteenth transistor including a base or a gate to which one of the signal of the negative phase side of the differential signal output from the delay circuit and the third control signal is input, and a collector or a drain connected to an emitter or a source of the tenth transistor and an emitter or a source of the eleventh transistor;
a fourteenth transistor including a base or a gate to which a bias voltage is applied;
a sixth resistor including one end connected to the power supply voltage, and another end connected to a collector or a drain of the eighth transistor and a collector or a drain of the eleventh transistor;
a seventh resistor including one end connected to the power supply voltage, and another end connected to a collector or a drain of the ninth transistor and a collector or a drain of the tenth transistor;
an eighth resistor including one end connected to an emitter or a source of the twelfth transistor, and another end connected to a collector or a drain of the fourteenth transistor;
a ninth resistor including one end connected to an emitter or a source of the thirteenth transistor, and another end connected to the collector or the drain of the fourteenth transistor; and
a tenth resistor including one end connected to an emitter or a source of the fourteenth transistor, and another end connected to ground.

9. The phase adjustment circuit according to claim 8, wherein the adder includes:
a fifteenth transistor including a base or a gate to which the signal of the negative phase side of the differential signal output from the first multiplier is input, and a collector or a drain from which the signal of the positive phase side is output;
a sixteenth transistor including a base or a gate to which the signal of the positive phase side of the differential signal output from the first multiplier is input, and a collector or a drain from which the signal of the negative phase side is output;
a seventeenth transistor including a base or a gate to which the signal of the positive phase side of the differential signal output from the second multiplier is input, and a collector or a drain from which the signal of the negative phase side is output;
an eighteenth transistor including a base or a gate to which the signal of the negative phase side of the differential signal output from the second multiplier is input, and a collector or a drain from which the signal of the positive phase side is output;
a nineteenth transistor and a twentieth transistor, each including a base or a gate to which a bias voltage is applied;
an eleventh resistor including one end connected to the power supply voltage, and another end connected to a collector or a drain of the fifteenth transistor and a collector or a drain of the eighteenth transistor;
a twelfth resistor including one end connected to the power supply voltage, and another end connected to a collector or a drain of the sixteenth transistor and a collector or a drain of the seventeenth transistor;
a thirteenth resistor including one end connected to an emitter or a source of the fifteenth transistor, and another end connected to a collector or a drain of the nineteenth transistor;
a fourteenth resistor including one end connected to an emitter or a source of the sixteenth transistor, and another end connected to the collector or the drain of the nineteenth transistor;
a fifteenth resistor including one end connected to an emitter or a source of the seventeenth transistor, and another end connected to a collector or a drain of the twentieth transistor;
a sixteenth resistor including one end connected to an emitter or a source of the eighteenth transistor, and another end connected to the collector or the drain of the twentieth transistor;
a seventeenth resistor including one end connected to an emitter or a source of the nineteenth transistor, and another end connected to ground; and
an eighteenth resistor including one end connected to an emitter or a source of the twentieth transistor, and another end connected to ground.

10. The phase adjustment circuit according to claim 8, wherein the delay circuit includes:
a plurality of delay circuits with different delay amounts; and
a switch inserted between the plurality of delay circuits and the second multiplier and configured to select any one output of the plurality of delay circuits.

11. The phase adjustment circuit according to claim 8, further comprising:
a level adjusting circuit configured to perform an amplitude adjustment of the signal output from the adder.

12. The phase adjustment circuit according to claim 7, wherein the adder includes:
a fifteenth transistor including a base or a gate to which a signal of a negative phase side of a differential signal output from the first multiplier is input, and a collector or a drain from which a signal of a positive phase side is output;
a sixteenth transistor including a base or a gate to which a signal of a positive phase side of the differential signal output from the first multiplier is input, and a collector or a drain from which a signal of a negative phase side is output;
a seventeenth transistor including a base or a gate to which a signal of a positive phase side of a differential signal output from the second multiplier is input, and a collector or a drain from which the signal of the negative phase side is output;
an eighteenth transistor including a base or a gate to which a signal of a negative phase side of the differential signal output from the second multiplier is input, and a collector or a drain from which the signal of the positive phase side is output;
a nineteenth transistor and a twentieth transistor, each including a base or a gate to which a bias voltage is applied;
an eleventh resistor including one end connected to a power supply voltage, and another end connected to a collector or a drain of the fifteenth transistor and a collector or a drain of the eighteenth transistor;
a twelfth resistor including one end connected to the power supply voltage, and another end connected to a collector or a drain of the sixteenth transistor and a collector or a drain of the seventeenth transistor;
a thirteenth resistor including one end connected to an emitter or a source of the fifteenth transistor, and another end connected to a collector or a drain of the nineteenth transistor;
a fourteenth resistor including one end connected to an emitter or a source of the sixteenth transistor, and another end connected to the collector or the drain of the nineteenth transistor;
a fifteenth resistor including one end connected to an emitter or a source of the seventeenth transistor, and another end connected to a collector or a drain of the twentieth transistor;
a sixteenth resistor including one end connected to an emitter or a source of the eighteenth transistor, and another end connected to the collector or the drain of the twentieth transistor;
a seventeenth resistor including one end connected to an emitter or a source of the nineteenth transistor, and another end connected to ground; and
an eighteenth resistor including one end connected to an emitter or a source of the twentieth transistor, and another end connected to ground.

13. The phase adjustment circuit according to claim 12, wherein the delay circuit includes:
a plurality of delay circuits with different delay amounts; and
a switch inserted between the plurality of delay circuits and the second multiplier and configured to select any one output of the plurality of delay circuits.

14. The phase adjustment circuit according to claim 12, further comprising:
a level adjusting circuit configured to perform an amplitude adjustment of the signal output from the adder.

15. The phase adjustment circuit according to claim 7, wherein the delay circuit includes:
a plurality of delay circuits with different delay amounts; and
a switch inserted between the plurality of delay circuits and the second multiplier and configured to select any one output of the plurality of delay circuits.

16. The phase adjustment circuit according to claim 15, further comprising:
a level adjusting circuit configured to perform an amplitude adjustment of the signal output from the adder.

17. The phase adjustment circuit according to claim 7, further comprising:
a level adjusting circuit configured to perform an amplitude adjustment of the signal output from the adder.

18. A phase adjustment circuit comprising:
a clock generator configured to generate a sinusoidal clock signal;
a delay circuit configured to delay a signal output from the clock generator; and
a process circuit including:
a first multiplier configured to output a signal obtained by multiplying an amplitude of the signal output from the clock generator by a first constant;
a second multiplier configured to output a signal obtained by multiplying an amplitude of the signal output from the delay circuit by a second constant; and
an adder configured to add the signal output from the first multiplier and the signal output from the second multiplier,
wherein the process circuit includes:
a first transistor including a base or a gate to which one of a first control signal and a signal of a negative phase side of the clock signal of a differential type is input, and a collector or a drain from which a signal of a positive phase side is output;
a second transistor including a base or a gate to which one of a second control signal and a signal of a positive phase side of the clock signal of the differential type is input, and a collector or a drain from which a signal of a negative phase side is output;
a third transistor including a base or a gate to which one of the first control signal and the signal of the negative phase side of the clock signal of the differential type is input, and a collector or a drain from which the signal of the negative phase side is output;
a fourth transistor including a base or a gate to which one of the second control signal and the signal of the positive phase side of the clock signal of the differential type is input, and a collector or a drain from which the signal of the positive phase side is output;
a fifth transistor including a base or a gate to which one of the signal of the positive phase side of the clock signal of the differential type and the second control signal is input, and a collector or a drain connected to an emitter or a source of the first transistor and an emitter or a source of the second transistor;
a sixth transistor including a base or a gate to which one of the signal of the negative phase side of the clock signal of the differential type and the first control signal is input, and a collector or a drain connected to an emitter or a source of the third transistor and an emitter or a source of the fourth transistor;
a seventh transistor including a base or a gate to which a bias voltage is applied;
an eighth transistor including a base or a gate to which one of a third control signal and a signal of a negative phase side of a differential signal output from the delay circuit is input, and a collector or a drain from which a signal of a positive phase side is output;
a ninth transistor including a base or a gate to which one of a fourth control signal and a signal of a positive phase side of the differential signal output from the delay circuit is input, and a collector or a drain from which a signal of a negative phase side is output;
a tenth transistor including a base or a gate to which one of the third control signal and the signal of the negative phase side of the differential signal output from the delay circuit is input, and a collector or a drain from which the signal of the negative phase side is output;
an eleventh transistor including a base or a gate to which one of the fourth control signal and the signal of the positive phase side of the differential signal output from the delay circuit is input, and a collector or a drain from which the signal of the positive phase side is output;
a twelfth transistor including a base or a gate to which one of the signal of the positive phase side of the differential signal output from the delay circuit and the fourth control signal is input, and a collector or a drain connected to an emitter or a source of the eighth transistor and an emitter or a source of the ninth transistor;
a thirteenth transistor including a base or a gate to which one of the signal of the negative phase side of the differential signal output from the delay circuit and the third control signal is input, and a collector or a drain connected to an emitter or a source of the tenth transistor and an emitter or a source of the eleventh transistor;
a fourteenth transistor including a base or a gate to which a bias voltage is applied;
a first resistor including one end connected to a power supply voltage, and another end connected to a collector or a drain of the first transistor, a collector or a drain of the fourth transistor, a collector or a drain of the eighth transistor and a collector or a drain of the eleventh transistor;
a second resistor including one end connected to the power supply voltage, and another end connected to a collector or a drain of the second transistor, a collector or a drain of the third transistor, a collector or a drain of the ninth transistor and a collector or a drain of the tenth transistor;
a third resistor including one end connected to an emitter or a source of the fifth transistor, and another end connected to a collector or a drain of the seventh transistor;
a fourth resistor including one end connected to an emitter or a source of the sixth transistor, and another end connected to the collector or the drain of the seventh transistor;
a fifth resistor including one end connected to an emitter or a source of the seventh transistor, and another end connected to ground;
a sixth resistor including one end connected to an emitter or a source of the twelfth transistor, and another end connected to a collector or a drain of the fourteenth transistor;
a seventh resistor including one end connected to an emitter or a source of the thirteenth transistor, and another end connected to the collector or the drain of the fourteenth transistor; and
an eighth resistor including one end connected to an emitter or a source of the fourteenth transistor, and another end connected to ground.

19. The phase adjustment circuit according to claim 18, wherein the delay circuit includes:
a plurality of delay circuits with different delay amounts; and
a switch inserted between the plurality of delay circuits and the second multiplier and configured to select any one output of the plurality of delay circuits.

20. The phase adjustment circuit according to claim 18, further comprising:
a level adjusting circuit configured to perform an amplitude adjustment of the signal output from the adder.
